(19) United States
(12) Patent Application Publication
(10) Pub. No.: US 2025/0048751 A1
(43) Pub. Date: Feb. 6, 2025

(54) A GRAPHENE PHOTODETECTOR

(71) Applicants: CAMGRAPHIC SRL, Monza (MB) (IT); CONSORZIO NAZIONALE INTERUNIVERSITARIO PER LE TELECOMUNICAZIONI, Parma (IT)

(72) Inventors: Marco ROMAGNOLI, Milano (IT); Vito SORIANELLO, San Giuliano Terme (PI) (IT); Alessio PIRASTU, Pisa (IT); Simone MARCONI, Frosinone (IT)

(73) Assignees: CAMGRAPHIC SRL, Monza (MB) (IT); CONSORZIO NAZIONALE INTERUNIVERSITARIO PER LE TELECOMUNICAZIONI, Parma (IT)

(21) Appl. No.: 18/716,952

(22) PCT Filed: Dec. 20, 2022
(86) PCT No.: PCT/EP2022/086960

§ 371 Date: Jun. 6, 2024

(30) Foreign Application Priority Data
Dec. 28, 2021 (IT) 102021000032822

(51) Int. Cl. H01L 31/113; H01L 31/0232; H01L 31/028

(52) U.S. Cl. CPC H01L 31/1136; H01L 31/02327; H01L 31/028

(57) ABSTRACT

A graphene photodetector includes a first graphene absorption layer connected to first and second metal electrodes, the first and second metal electrodes defining a channel on the first graphene layer operating as a plasmonic waveguide, a gate dielectric layer interposed between the first graphene layer and a second graphene layer. The second graphene layer used for electrical gating and includes first and second gate electrodes proximate to the first and the second metal electrodes, respectively. The photodetector also includes a photonic dielectric waveguide with a planarized cladding underneath the gate dielectric layer, the first and second gate electrodes remaining interposed therebetween. The distance between the first and the second metal electrodes, defining the width of the channel cross-section, is between 100 nm and 600 nm, and the distance between the first and second gate electrodes is at least 60% of the distance between the first and second metal electrodes.

### TECHNICAL FIELD

The present invention relates to a graphene photodetector, in particular to a graphene photodetector exploiting the photo-conversion mechanism based on photo-thermoelectric and photo-voltaic effect.

### TECHNOLOGICAL BACKGROUND

Graphene photodetectors offer several advantages in a range of applications, in particular for high speed data and telecommunication applications due to the graphene properties.

Graphene is a one-atom-thick layer of carbon having a two-dimensional hexagonal structure with sp² hybridization. The valence and the conduction band of this material meet in six points in the reciprocal space called Dirac points.

Graphene has a low density of states linearly varying with the energy of the electronic states and vanishing at the Dirac point. Such a feature enables an easy tuneability of the chemical potential (low gate voltage is required to shift the chemical potential if compared to other materials like Silicon) and all the material properties associated with it (e.g., electrical conductivity, Seebeck coefficient, optical absorption, etc.) by means of field effect. This feature is referred to as electrostatic doping.

The optical absorption spectrum for graphene spans from the UV to the far IR and the charge carriers' mobility in graphene can exceed 100.000 cm²/Vs even at room temperature when the material is properly encapsulated (e.g., in hBN).

The fast carrier dynamics of optically excited carriers upon optical excitation owing to the short relaxation time (of the order of picoseconds) and the small electronic heat capacitance enables the realization of photodetectors having opto-electronic bandwidths larger than 100 GHz.

In addition, graphene can be grown by chemical vapor deposition (CVD) on a proper substrate (e.g., copper) and transferred on virtually any photonic substrate.

Use of graphene photodetectors based on the photo-thermoelectric effect, mainly allows for direct optical power to voltage conversion, zero dark current, and ultra-fast operation.

Photo-thermal effect (PTE) is based on an increase of the temperature of the electronic system following the absorption of optical power. In PTE based graphene photodetectors, the electromotive force is generated by the Seebeck effect caused by the spatial gradient of the electronic temperature in graphene in presence of a spatially non-homogeneous Seebeck coefficient.

For a better understanding of this concept, if it is assumed that a laser beam excites an active graphene layer which has a spatially homogeneous chemical potential and thus a Seebeck coefficient (property depending on the chemical potential) constant along the channel, the hot carriers optically excited within the laser spot region (i.e., electrons and holes found at higher temperature with respect to the lattice after illumination), radially diffuse from the center of the excitation region to the sides. In this condition hot electrons (or holes depending on the sign of the Seebeck coefficient) diffuse in opposite directions giving rise to a zero net photocurrent. To the contrary, if a step change of the chemical potential (and consequently of the Seebeck coefficient) is induced at the center of the excitation region, hot electrons or holes will diffuse in the same direction giving rise to a net photocurrent. Since the photo response is directly generated by a thermoelectric effect, differently from other effects (photo-conductive and photo-bolometric effect, for example), the photo-thermoelectric effect does not require a bias applied to the active graphene layer and, thus, operates in absence of dark current.

Both the photo-voltaic and the photo-thermoelectric effect require, for different reasons, a non-homogeneous chemical potential, i.e., a pn junction. There are remarkable differences between the graphene pn homojunctions (where the junction is made only of graphene) and the classical semiconductor-based diodes.

The first difference is that a classical semiconductor requires physical doping to realize a pn junction. Differently, the easy tuneability of graphene chemical potential through field effect enables the realization of electrostatically induced pn homojunctions by using proper gating structures. Several gating configurations are reported in literature combining top gate configurations (gate electrodes are placed on top of the active graphene layer) and bottom gate configurations (gate electrodes are placed under the active graphene layer). Just as an example, reference is made in the following to the top split gate and the bottom split gate configuration.

In a split gate configuration two gate electrodes separated by a small gap (usually less than 300 nm) are used to induce in the active layer a spatial doping profile with opposite sign in the two sides of the junction. Two examples of top and bottom split gate configuration related to waveguide integrated graphene photodetectors are shown in FIGS. 1a to 1d.

In FIG. 1a (bottom gate configuration, zero bias detector operation) and 1c (bottom gate configuration, unbiased operation), the two parts of a doped silicon slot waveguide are used as gate electrodes under the active graphene channel. This solution avoids the deposition of a dielectric on top of the active layer preventing the degradation of its electrical properties. However, bottom gates constraint the design to the use of doped silicon for gate electrodes realization. Other photonic platforms like SiN are not usable. The use of the chemical doping removes an advantage of graphene, which does not require doping. Other possible bottom gate configurations for waveguide integrated photodetectors are not feasible since a conductive layer interposed between the waveguide and the active graphene layer would absorb a larger amount of optical power with respect to the active channel. Optical power absorbed by the gates does not contribute to the photocurrent so that the responsivity is reduced.

In the top split gate configuration of FIG. 1b (top gate configuration, zero bias operation) and FIG. 1d (top gate configuration, unbiased operation) two graphene gate electrodes are placed on a thick gate dielectric (thickness greater than 100 nm) deposited on top of the active channel. Since the graphene gates are placed at a large distance from the waveguide, optical power absorbed in the gate layer accounts for about 10% of the total absorption. However, charge carriers' mobility is affected by the deposition process as outlined in Giambra et al., Optics express 27 (15), 20145-20155. The second remarkable difference between graphene pn homojunction and classical semiconductor pn junctions is that, due to the semimetal nature of graphene, a graphene pn homojunction has no rectifying behavior. When a bias is applied to the graphene pn junction, whatever is the polarity of the bias with respect to the p- or n-side, a large current (even mA's current depending on sample resistance and applied bias) will flow, i.e., a reverse bias condition where the diode dark current is suppressed does not exist. Thus, the only possibility to realize a photodetector operating with low or zero dark current is to use the photo-voltaic or the photo-thermoelectric effect since those effects do not require a bias.

FIGS. 1a, 1b and 1c, 1d show the difference between two photodetector operations: zero bias and unbiased operation. In FIGS. 1a, 1b the integrated photodetector operates in zero bias condition, i.e. the drain electrode (right metal electrode) is grounded through an inductor. In FIGS. 1c, 1d the photodetector is directly connected to the electronics for data read-out (amplifier in the figures) without applying an external bias. In both cases, only the photocurrent is present (zero dark current operation). In the unbiased operation it is preferable to express the responsivity in terms of voltage responsivity (V/W) corresponding to the photovoltage to the incident optical power ratio.

### DESCRIPTION OF THE INVENTION

A main object of the invention is to provide a graphene photodetector to overcome the limits highlighted with reference to known solutions.

This object and others that will be more apparent hereinafter are achieved by a graphene photodetector made in accordance with the appended claims.

According to one aspect of the disclosed subject matter, the invention relates to a graphene photodetector comprising:
a first graphene absorption layer connected to a first metal electrode at a first end of said first graphene layer and to a second electrode at a second end of the first graphene layer opposite to the first end, said first and second metal electrode being referred to as source and drain, respectively,
said first and second metal electrode defining on said first graphene layer a channel and also a plasmonic waveguide,
a gate dielectric layer interposed between the first graphene layer and a second graphene layer,
said gate dielectric layer being placed on the opposite side of the channel with respect to the first graphene layer,
said second graphene layer being used for electrical gating and comprising a first and a second gate electrode proximate to the first metal electrode and the second metal electrode, respectively,
said first and second gate electrode being centered with respect to said channel,
a photonic dielectric waveguide with a planarized cladding disposed underneath the gate dielectric layer, with the first and second gate electrode remaining interposed between the gate dielectric layer and the cladding,
the distance between the first and the second metal defining the width of the channel cross-section, being comprised between 100 nm and 600 nm, the distance between the first and second gate electrode being at least 60% of the distance between said first and second metal electrode.

In some embodiments, the width of said channel can be further preferably comprised between 250 nm and 450 nm.

In some embodiments, the thickness of the first and second metal electrode, defining the height of the channel cross-section, is comprised between 70 nm and 200 nm.

In some embodiments, the thickness of the first and second metal electrode is preferably 100 nm.

In some embodiments, the thickness of the gate dielectric layer is comprised between 10 nm and 40 nm.

In some embodiments, the thickness of the dielectric layer is preferably 20 nm.

In some embodiments, the first and/or the second metal electrode are made of one or more of the following metals: Gold, Silver, Aluminum, Titanium nitride (TIN), or alloy thereof.

In some embodiments, the distance between the first and the second metal electrode, defining the width of the channel cross-section, is constant in the longitudinal extension of the channel.

In some embodiments, the constant width of the channel cross section is comprised between 250 nm and 450 nm.

In some embodiments, the width of the channel is periodically variable in the longitudinal extension of the channel, with sections having a minimum width alternating with sections having a maximum width, and in which the width varies gradually between the minimum value and the maximum value, and vice versa, along said longitudinal direction.

In some embodiments, the minimum width is comprised between 100 nm and 250 nm and the maximum width is comprised between 450 nm and 600 nm

In some embodiments, the number of channel sections having the minimum width is comprised between two and five.

In some embodiments, in said channel three sections having the minimum width are provided.

In some embodiments, between two sections of minimum and maximum width, adjacent to each other, the opposite surfaces of the channel are angled at an angle between 4° and 23° degrees, with respect to the longitudinal extension direction of the channel.

In some embodiments, the optical mode of the dielectric waveguide has to be quasi-Transverse-Electric (quasi-TE).

In some embodiments, said channel can be realized by using more than one graphene layer, preferably two graphene layers. Preferably the two layers of graphene are superimposed on each other.

### BRIEF DESCRIPTION OF THE DRAWINGS

Further features and advantages of the invention will be made clearer by the detailed description hereinafter of some of its preferred embodiments illustrated, by way of non-limiting example, with reference to the accompanying drawings, in which:

FIGS. 1a to 1d are schematic views showing the cross sections of respective graphene photodetector embodiments according to the prior art,

FIG. 2 is a schematic cross section of a graphene photodetector realized according to the present invention,

FIGS. 3 and 4 are schematic top views of respective embodiments of the photodetector realized according to the invention,

FIG. 5 is a schematic top view, in enlarged scale, of a particular shown in FIG. 4,

FIG. 6 is a graph showing the ratio between the power absorbed by the active graphene layer and the power absorbed by the graphene gate electrodes shown versus the gate dielectric thickness, in the photodetector of the invention,

FIG. 7 is a schematic top view, in enlarged scale, showing the region of the gap between the metal electrodes, provided in the active graphene channel of the photodetector of the invention,

FIG. 8 is a graph showing the absorbed optical power density at a gold/graphene interface for selected gap widths, in the photodetector of the invention,

FIG. 9 is a graph showing the voltage responsivity in the photodetector of the invention as a function of the gap width,

FIG. 10 is a graph showing the power absorbed by metals and the power absorbed in the active graphene channel of the photodetector as respective functions of the metal electrode thickness,

FIG. 11 is a graph showing the optical absorption in the active graphene channel of the photodetector versus the distance between the dielectric layer and the dielectric waveguide,

FIG. 12 is a graph showing the optical absorption in the active graphene channel of the photodetector versus the thickness of the dielectric layer.

### PREFERRED EMBODIMENTS OF THE INVENTION

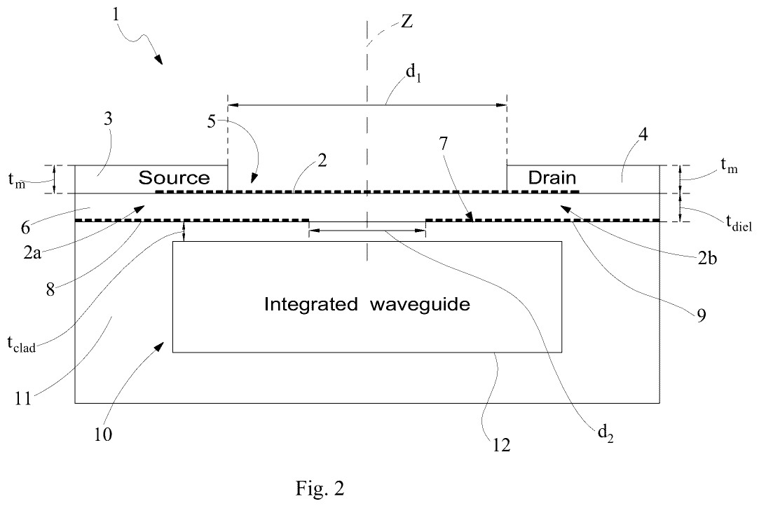

With initial reference to FIG. 2, a graphene photodetector realized according to an embodiment of the present invention is globally indicated with 1. In FIG. 2 a schematic view of the cross section of the photodetector 1 is shown.

The photodetector 1 comprises a first graphene absorption layer 2 (having a planar configuration depicted with a dashed line) connected to a first metal electrode 3 at a first end 2a of the first graphene layer 2 and to a second metal electrode 4 at a second end 2b of the first graphene layer 2 opposite to the first end 2a. The first and second metal electrode 3, 4 are referred to as source and drain, respectively.

The contact between the graphene layer 2 and each of the metal electrode 3, 4 ensures the appropriate electrical connection to conduct and detect the photocurrent produced in the photodetector.

The first 3 and/or the second metal electrode 4 are preferably made of one or more of the following metals: Gold, Silver, Aluminum, Titanium nitride (TiN), or alloy thereof.

The first and second metal electrode 3, 4 further define on the first graphene layer 2 a channel 5 operating as a plasmonic waveguide, as clearly disclosed in the following.

The first and second metal electrode 3,4 are spaced apart and the distance between the first and the second metal electrode, indicated d₁, defines the width of the channel cross-section.

The thickness of the first and second metal electrode, indicated tₘ, defines the height of the channel cross-section and is preferably comprised between 70 nm and 200 nm, and more preferably is 100 nm.

Preferably the distance d₁ between the first and second metal electrode 3,4 is comprised between 100 nm and 600 nm, and more preferably is comprised between 250 nm and 450 nm.

The photodetector 1 further comprises a gate dielectric layer 6 interposed between the first graphene layer 2 and a second graphene layer 7 (also depicted with a dashed line), such a configuration realizing a capacitor, where the dielectric layer 6 is placed on the opposite side of the channel 5 with respect to the first graphene layer 2. Preferably the dielectric layer 6 is made of SiN or Al₂O₃.

The first and second graphene layer 2, 7 are preferably planar and parallel to each other, the distance between them being defined by the thickness of the dielectric layer 6, indicated t_{diel}.

The second graphene layer 7 is used for electrical gating and comprises a first and a second gate electrode, indicated 8,9, which are located proximate to the first metal electrode 3 and the second metal electrode 4, respectively, in at least partial overlapping with the first graphene layer 2.

Preferably the first and second gate electrode 8,9 are spaced apart with a distance d₂ and have a configuration centered with respect to the channel 5, as clearly shown in FIG. 2. The centered configuration means that the gating electrode 8,9 are arranged in a specularly symmetrical way with respect to a hypothetical median plane of symmetry of the cross section channel 5, identified in FIG. 2 with an axis indicated Z.

Preferably, the distance d₂, between the gating electrodes 8,9 is at least 60% of the distance between said first and second metal electrode 3,4, and more preferably the distance d₂ is comprised between 100 nm and 300 nm. In this range, more preferably the value of d₂ is 150 nm.

As further disclosed below, the metal electrodes 3,4 on top of the first graphene layer 2, defining the active channel 5, are provided to either collect the photocurrent and to confine the light at the metal-graphene interface. Control of the electrostatic doping in the active channel, by changing the graphene chemical potential (applying an external voltage to the gating electrodes) is achieved by using a so called bottom split gate geometry obtained by the gating electrodes 8,9 of the second graphene layer 4.

The photodetector 1 further comprises a photonic dielectric waveguide 10 with a planarized cladding 11 disposed underneath the dielectric layer 6, with the first and second gating electrode 8, 9 remaining interposed between the dielectric layer 6 and the cladding 11. The waveguide 10 includes a core 12, preferably a silicon core, embedded in the cladding 11, preferably a SiO₂ cladding.

The waveguide 10, preferably configured in a rectangular cross-section, is located centrally with respect to the active graphene channel 5. The dielectric spacer thickness between the waveguide 10 and the graphene gate electrodes is indicated by t_{clad}. Preferably the waveguide 10 can have a rectangular cross section of 220 nm by 480 nm.

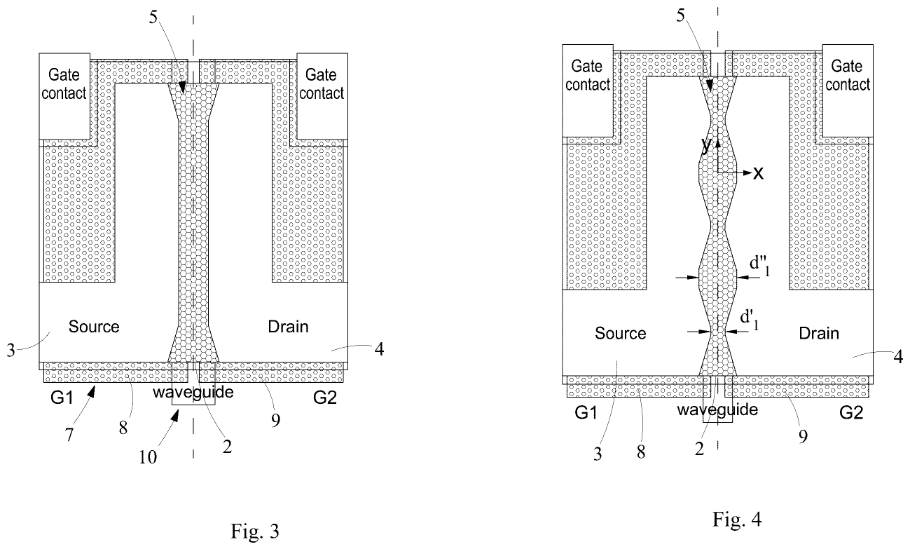

Referring to the top view of FIG. 3, the active channel 5 as well as the waveguide 10 are extended along a prevailing longitudinal direction, identified by the Y axis in the Figure. X indicates the direction perpendicular to the Y axis and directed parallel to the first graphene layer 2. The distance d₁, defining the gap between the metal electrodes 3, 4 in the active graphene channel 5 is measured along the transverse direction X.

According to one embodiment of the invention, shown in the top view of FIG. 3, the distance d₁ between the first and the second metal electrode 3, 4, defining the width of the active graphene channel 5, is constant along the longitudinal extension Y of the channel. This configuration is obtained by making the facing edges of the respective metal electrodes 3,4, parallel to each other, and spaced by the gap distance d₁, for the prevailing longitudinal extension.

According to another embodiment of the invention, shown in the top view of FIG. 4, the distance d₁, defining the width of the channel 5, may be periodically variable in the longitudinal extension of the channel, with channel sections having a minimum width, indicated d₁′, alternating with sections having a maximum width, indicated d₁″, and in which the width varies gradually between the minimum value d₁′ and the maximum value d₁″, and viceversa, along the longitudinal direction Y.

Preferably the minimum width d₁′ is comprised between 100 nm and 300 nm and the maximum width d₁″ is comprised between 450 nm and 600 nm. Preferably, the number of channel sections having the minimum width d₁′ may be comprised between two and five, and more preferably three channel sections having the minimum width d₁′ may be provided in the longitudinal extension of the channel.

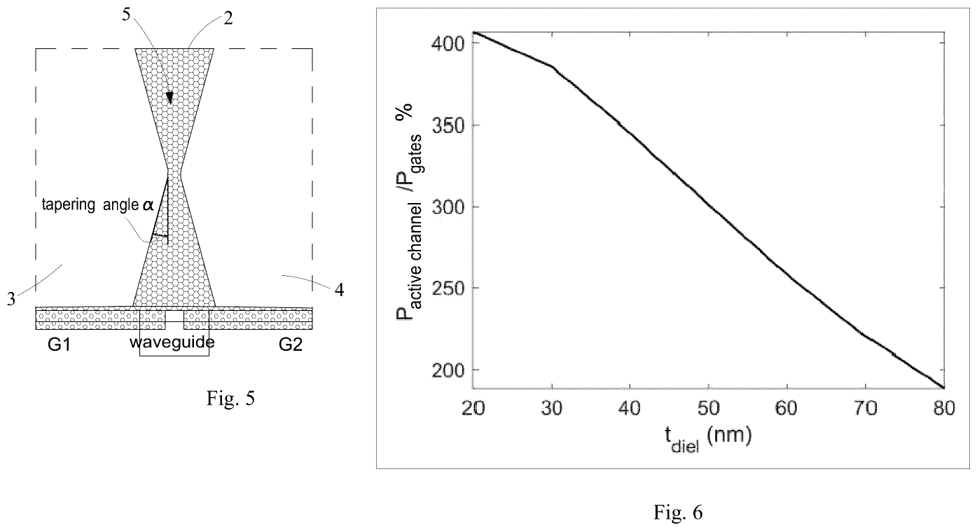

In FIG. 5, the tapering configuration of the channel sections of FIG. 4 is shown in an enlarged scale. In the tapering configuration, the opposite surfaces of the channel are angled at an angle α with respect to the longitudinal extension direction of the channel.

A small tapering angle α (see FIG. 5) is desirable in order to efficiently convert the mode of the dielectric waveguide into the plasmonic mode of the detector structure. However, an excessively small tapering angle would lead to a long (in the propagation direction y) tapering section. This would be detrimental because losses in metal would increase with consequent reduction of responsivity. A preferred angle α is defined in the range between 4° and 23°. The distance between the gate electrodes and the dielectric waveguide (t_{clad}, see FIG. 2) must be small enough to ensure good coupling between the dielectric waveguide and the detector stack. However, gate electrodes are electrically isolated. For this reason t_{clad}≠0.

The thickness t_{diel} of the gate dielectric layer is chosen small enough to maximize the optical absorption in the active graphene channel. However, the thickness t_{diel} is preferably chosen to be at least 20 nm to prevent current leakage between the active channel and the gate electrodes.

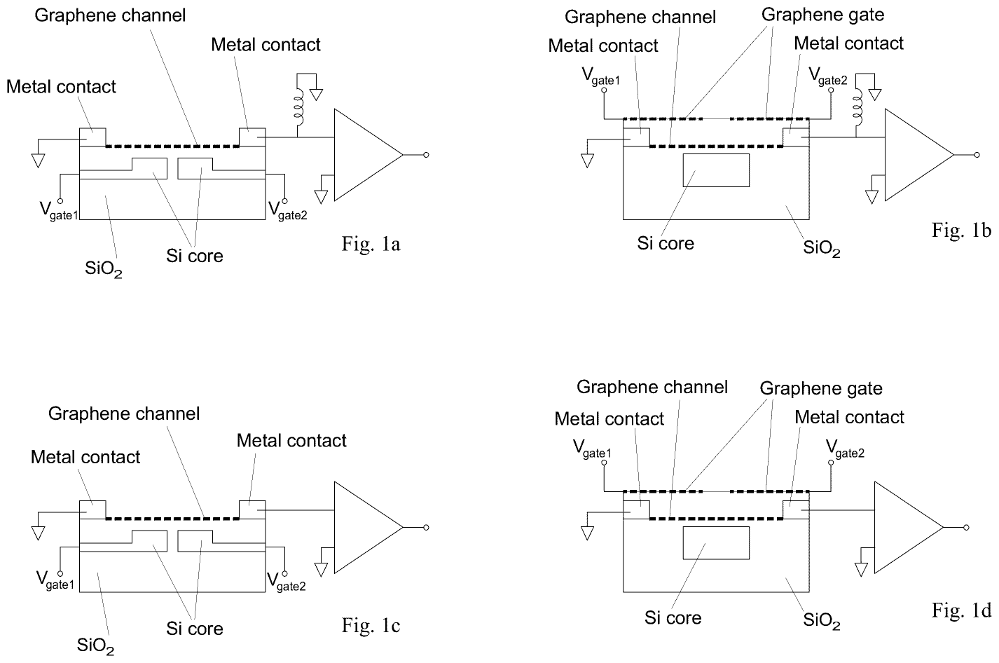

The graphene-based photodetector of the claimed subject matter is proposed for exploiting the photo-conversion mechanisms (photovoltaic and photo-thermoelectric effect) occurring at the metal/graphene interface. Photovoltaic and photo-thermoelectric mechanism at the metal/graphene interface can be exploited to generate a photocurrent. Differently from the devices of the prior art, described with reference to FIGS. 1a to 1d, where a graphene homojunction is used, the photovoltaic effect is expected to give a relevant contribution, in addition to the photo-thermoelectric effect. The basic idea behind the claimed photodetector is to use a plasmonic waveguide to confine the optical field at the edges of the metal electrodes (source and drain) used to collect the photocurrent. This photodetector structure is designed to be integrated on top of the photonic dielectric waveguide 10 with the planarized cladding 11 and it is made up of a stack of the two graphene layers 2, 7 separated by the dielectric layer 6. The metal electrodes 3,4 on top of the first graphene layer 2 (active channel 5) are used to either collect the photocurrent and to confine the light at the metal/graphene interface. Control of the doping in the active channel 5 (first graphene layer 2) is achieved by using the bottom split gate geometry obtained by the second graphene layer 7.

The geometry of the photodetector is shown in FIGS. 2-4, where the device stack is integrated on top of the photonic waveguide 10 with the core 12 and the planarized cladding 11. The source and drain electrodes 3, 4 serve both as electrodes to collect the photocurrent and as plasmonic waveguide to confine the light at the metal/graphene interface.

In order to excite the plasmonic mode the optical mode of the dielectric waveguide has to be quasi-Transverse-Electric (quasi-TE).

The light from the dielectric waveguide 10 is coupled to the plasmonic mode of the Metal-Insulator-Metal (MIM) waveguide on top of the active graphene channel 5. Most of the optical power is absorbed at the graphene/metal interface at the edge of the metal contacts. Referring to FIG. 3, the width d₁ of the MIM before metal absorption prevails on the graphene absorption is 300 nm.

In FIG. 4, in which the distance between metals varies periodically, regions where the MIM has a large width (d₁ greater than 300 nm) and regions of small width (d₁ less than 300 nm) are alternated.

As described above, with reference to the prior art solutions, a graphene layer interposed between the dielectric waveguide and the active graphene layer is detrimental because it would absorb a large amount of the optical power reducing the responsivity of the photodetector. In the proposed invention this problem is strongly mitigated. As a matter of fact, the use of a plasmonic waveguide enhances the electric field in the active graphene layer. Moreover, graphene optical absorption linearly scales with the number of layers. By using two graphene layers the active channel has a larger absorption with respect to gates.

In the graph of FIG. 6 the ratio between the power absorbed by the active graphene layer and the power absorbed by the graphene gate electrodes is shown as a function of the gate dielectric thickness (t_{diel}). In this case the t_{clad} is always 20 nm. The ratio of power absorbed by the active layer vs graphene gate electrodes spans from slightly more than 400% for a 20 nm thick layer to slightly less than 200% for a 80 nm thick gate dielectric. The graph has a monotonic decreasing trend, showing that the graphene gates absorb a significantly large part of the optical power when the thickness (t_{diel}) of the gate dielectric is increased.

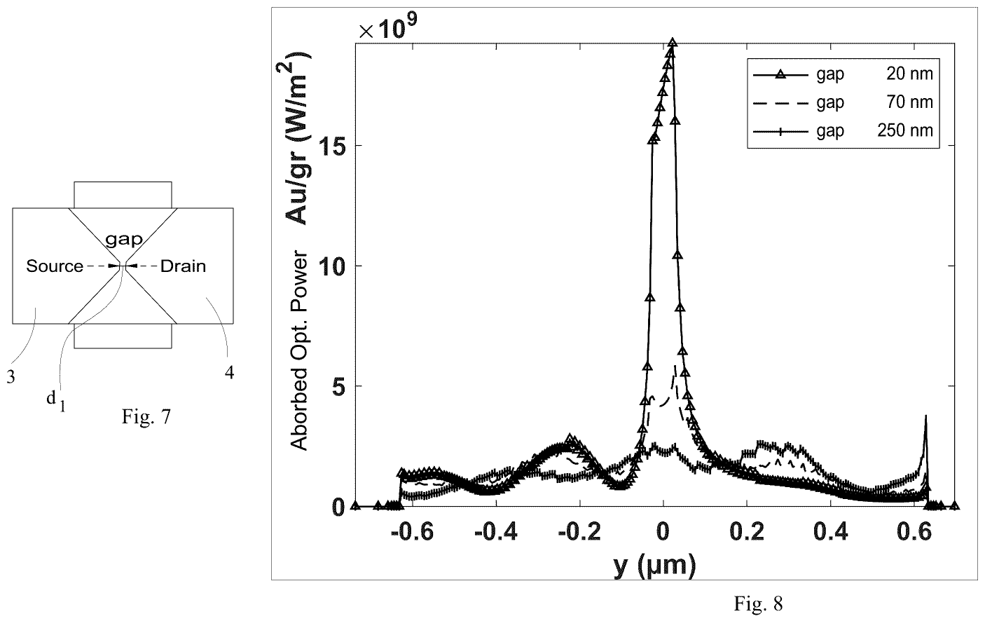

As to the graphene active channel, the major drawbacks of small gaps between the metal electrodes are the large absorption in metals and the non-trivial control of graphene chemical potential between the two metal electrodes. With small gaps, as it has been observed by the Applicant with a gap of 20 nm, the chemical potential in the gap is almost constant and does not vary from the left contact to the right contact. Since the gap region of the channel is the region where the largest part of the optical power is absorbed, if it not possible to control the chemical potential in the gap, it is not possible to maximize the PTE and PV photo-response. As a consequence of that, the voltage responsivity is poor. However, thanks to the field enhancement obtained in the gap, the embodiment with tapered sections has the advantage of increasing the amount of optical power absorbed in the active graphene channel. Two embodiments of the photodetectors can be compared: 1—a realization of photodetector having a constant width of 300 nm and 2—a photodetector with tapered sections having for instance a minimum width d₁′ equal to 250 nm and a maximum width d₁″ equal to 600 nm. In the realization constant width photodetector the absorbed optical power is less compared to the case of photodetector with periodically tapered width. Moreover, thanks to a minimum gap width (>100 nm), in the periodically tapered realizations the optical power is not confined only in the gap but a relevant part of the absorption occurs also in sections of the taper having larger width. FIG. 8 showing the optical power absorbed at the metal graphene interface as a function of the Y coordinate highlights this concept. In this system of coordinates Y=0 corresponds to the middle of the structure shown in FIG. 7. For tapers having minimum gap width of 20 nm, the optical power is absorbed almost entirely in the gap region. For devices having minimum gap width of 250 nm and of 70 nm the power is absorbed more uniformly along Y.

Optical power absorption in regions where the width is larger than 100 nm allows a more accurate control the chemical potential. This permits a better optimization of the PTE and PV effect and therefore the responsivity of the detector can be optimized.

For such reasons the solution with tapered sections and relatively large gap (>100 nm) represents the optimum design and the optimal range for d₁′ and d₁″ (see FIG. 4) is defined consequently.

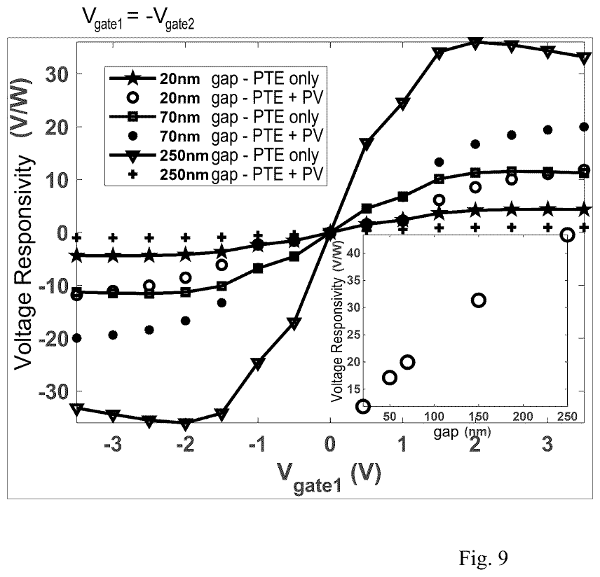

In the graph of FIG. 9 the simulated voltage responsivity as a function of the gap width is shown.

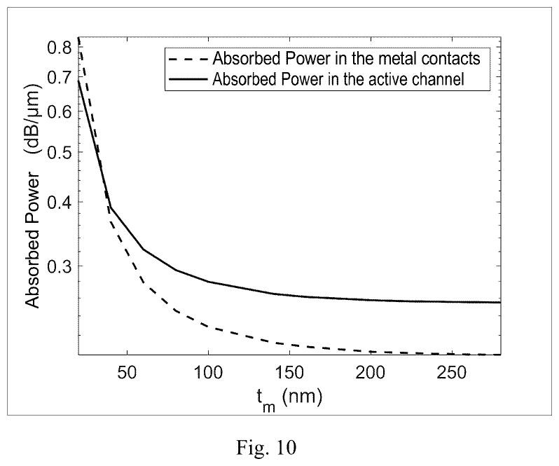

FIG. 10 is a graph showing the power absorbed by metals and the power absorbed in the active channel in function of the metal electrode thickness tₘ, wherein t_{clad} is 20 nm and t_{diel} is also 20 nm. It is observed that the power absorption in the metals is reduced as the metal thickness is increased.

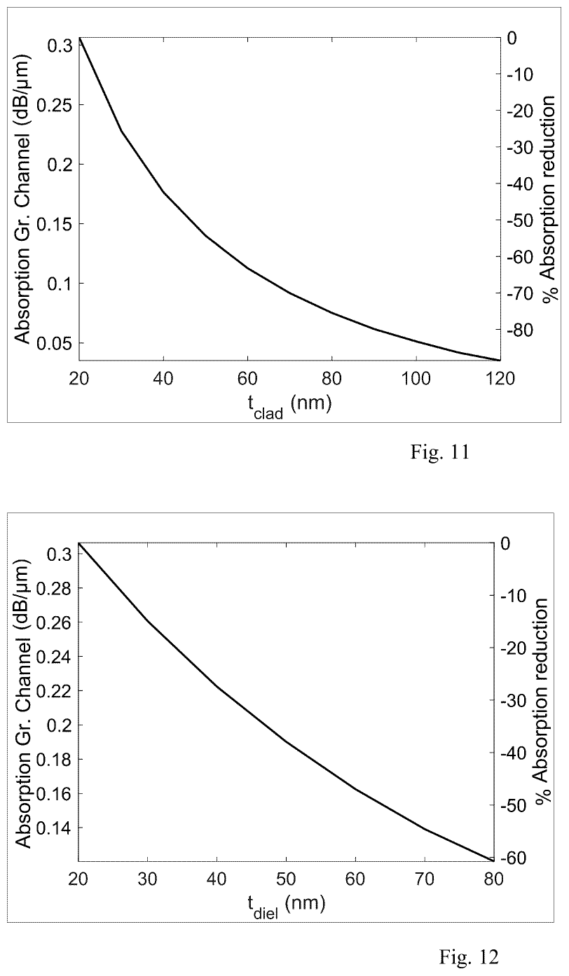

FIG. 11 is a graph showing the optical absorption in the active graphene channel versus the distance t_{clad}, where the t_{diel} is 20 nm and tₘ is 70 nm. The distance t_{clad} must be chosen as thin as possible to maximize the optical absorption in the active graphene channel. It can be observed that for t_{clad}=50 nm, the power absorbed in the active channel is reduced by 54% with respect to t_{clad}=20 nm.

FIG. 12 is a graph showing the optical absorption in the active channel versus the thickness t_{diel} of the dielectric layer, where t_{clad} is 20 nm and tₘ is 70 nm. It can be observed that for t_{diel}=50 nm, the power absorbed in the active channel is reduced by 60% with respect to t_{diel}=20 nm.

1. A graphene photodetector comprising:
a first graphene absorption layer (2) connected to a first metal electrode (3) at a first end (2a) of said first graphene layer (2) and to a second electrode (4) at a second end (2b) of the first graphene layer opposite to the first end (2a), said first and second metal electrodes (3, 4) being referred to as source and drain, respectively,
said first and second metal electrodes (3, 4) defining on said first graphene layer (2) a channel (5) operating as a plasmonic waveguide,
a gate dielectric layer (6) interposed between the first graphene layer (2) and a second graphene layer (7),
said gate dielectric layer (6) being placed on the opposite side of the channel (5) with respect to the first graphene layer (2),
said second graphene layer (7) being used for electrical gating and comprising first and second gate electrodes (8, 9) proximate to the first metal electrode (3) and the second metal electrode (4), respectively,
said first and second gate electrodes (8, 9) being centered with respect to said channel (5),
a photonic dielectric waveguide (10) with a planarized cladding (11) disposed underneath the gate dielectric layer (6), with the first and second gate electrodes (8, 9) remaining interposed between the gate dielectric layer (6) and the cladding (11),
a distance between the first and the second metal electrodes (3, 4), defining the width of the channel cross-section, being comprised between 100 nm and 600 nm,
a distance between the first and second gate electrodes (8, 9) being at least 60% of the distance between said first and second metal electrodes (3, 4).

2. The graphene photodetector according to claim 1, wherein the width of said channel (5) is between 250 nm and 450 nm.

3. The graphene photodetector according to claim 1, wherein a thickness of the first and second metal electrodes (3, 4), defining a height of the channel cross-section, is between 70 nm and 200 nm.

4. The graphene photodetector according to claim 3, wherein the thickness of the first and second metal electrodes (3, 4) is 100 nm.

5. The graphene photodetector according to claim 1, wherein a thickness of the gate dielectric layer (6) is comprised between 10 nm and 40 nm.

6. The graphene photodetector according to claim 1, wherein the thickness of the dielectric layer (6) is 20 nm.

7. The graphene photodetector according to claim 1, wherein the first and/or the second metal electrode (3, 4) are made of at least one of the following metals: Gold, Silver, Aluminum, Titanium nitride (TiN), or alloys thereof.

8. The graphene photodetector according to claim 1, wherein the distance (d₁) between the first and the second metal electrode (3, 4), defining the width of the channel cross-section, is constant in the longitudinal extension (Y) of the channel (5).

9. The graphene photodetector according to claim 8, wherein the constant width of the channel cross section is between 250 nm and 450 nm.

10. The graphene photodetector according to claim 1, wherein the width of the channel (5) is periodically variable in the longitudinal extension (Y) of the channel, with sections having a minimum width (d₁′) alternating with sections having a maximum width (d₁″), and in which the width varies gradually between the minimum value and the maximum value, and vice versa, along said longitudinal direction.

11. The graphene photodetector according to claim 10, wherein the minimum width (d₁′) is between 100 nm and 250 nm and the maximum width (d₁″) is comprised between 450 nm and 600 nm.

12. The graphene photodetector according to claim 10, wherein the number of channel sections having the minimum width (d₁′) is between two and five.

13. The graphene photodetector according to claim 12, wherein in said channel, three sections having the minimum width (d₁′) are provided.

14. The graphene photodetector according to claim 10, wherein between two sections of minimum (d₁′) and maximum width (d₁″), adjacent to each other, the opposite surfaces of the channel (5) are angled at an angle (α) between 4° and 23° degrees, with respect to the longitudinal extension direction of the channel (5).

15. The graphene photodetector according to claim 1, wherein an optical mode of the dielectric waveguide has to be is quasi-Transverse-Electric (quasi-TE).

16. The graphene photodetector according to claim 1, wherein said channel (5) can be realized by using more than one graphene layer.
